(19) United States
(12) Patent Application Publication
(10) Pub. No.: US 2024/0128414 A1
(43) Pub. Date: Apr. 18, 2024

(54) LIGHT-EMITTING DEVICE

(71) Applicant: Lextar Electronics Corporation, Hsinchu City (TW)

(72) Inventors: Shiou-Yi KUO, Hsinchu City (TW); Chin-Hung LUNG, Hsinchu City (TW); Yu-Chun LEE, Hsinchu City (TW); Hung-Chun TONG, Hsinchu City (TW)

(21) Appl. No.: 18/482,331

(22) Filed: Oct. 6, 2023

(30) Foreign Application Priority Data
Oct. 12, 2022 (TW) 111138545

(51) Int. Cl. H01L 33/50; H01L 25/075

(52) U.S. Cl. CPC H01L 33/507; H01L 25/0753; H01L 33/502; H01L 2933/0041

(57) ABSTRACT

A light-emitting device is provided. The light-emitting device includes a light-emitting unit and a light-conversion structure disposed on the light-emitting unit, wherein the light-conversion structure includes a quantum dot layer and an etching blocking layer disposed on one of the surfaces of the quantum dot layer.

### CROSS REFERENCE TO RELATED APPLICATIONS

This application claims the right of priority based on TW application Serial No. 111138545, filed on Oct. 12, 2022, which is incorporated by reference herein in its entirety.

### FIELD OF DISCLOSURE

The present disclosure relates to a light-emitting device and in particular to a light-emitting device including a light-conversion structure disposed on a light-emitting unit.

### BACKGROUND OF THE DISCLOSURE

Currently, micro LED display technology mainly uses red, green and blue light-emitting diodes as three primary color light sources. But the red light-emitting diode has poor efficiency and is difficult to process, and the green light-emitting diode has wider wavelength coverage, the overall cost and process complexity impose a great challenge.

### SUMMARY OF THE DISCLOSURE

The present disclosure provides a light-emitting device. The light-emitting device includes a light-emitting unit, and a light-conversion structure disposed on the light-emitting unit, in which the light-conversion structure includes a quantum dot layer and the quantum dot layer has surfaces, and an etching blocking layer disposed on one of the surfaces of the quantum dot layer.

According to various embodiments of the present disclosure, a method of forming light-emitting device includes providing a substrate; forming an adhesive layer on the substrate; forming a quantum dot layer on the adhesive layer; forming an etching blocking layer disposed on one of the surfaces of the quantum dot layer; using the etching blocking layer as a patterned mask; performing a patterning process to form a light-conversion structure; providing a light-emitting unit; and performing a transfer process so as to transfer the light-conversion structure onto the light-emitting unit.

### BRIEF DESCRIPTION OF THE DRAWINGS

FIG. 1 shows a schematic sectional view of a light-emitting device in accordance with an embodiment of the present disclosure.

FIG. 2A shows a schematic sectional view of a light-conversion structure of the light-emitting device in accordance with an embodiment of the present disclosure.

FIG. 2B shows a schematic sectional view of a light-conversion structure of the light-emitting device in accordance with another embodiment of the present disclosure.

FIG. 3 shows a schematic sectional view of a light-conversion structure of the light-emitting device in accordance with another embodiment of the present disclosure.

FIG. 4 shows a schematic sectional view of a light-emitting device in accordance with another embodiment of the present disclosure.

FIGS. 5A-5G show schematic sectional views of a method for producing a light-emitting device in accordance with an embodiment of the present disclosure.

FIGS. 6A-6G show schematic sectional views of a method for producing a light-emitting device in accordance with another embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

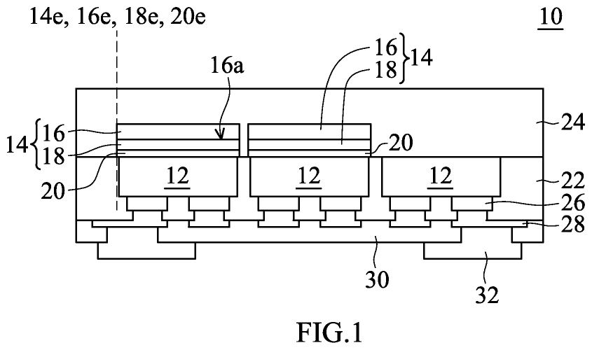

Referring to FIG. 1, a light-emitting device 10 in accordance with the present disclosure is provided. FIG. 1 shows a schematic sectional view of the light-emitting device 10.

Referring to FIG. 1, the light-emitting device 10 includes a light-emitting unit 12 and a light-conversion structure 14. The light-conversion structure 14 is disposed on the light-emitting unit 12. The light-conversion structure 14 includes a quantum dot layer 16 and an etching blocking layer 18. The etching blocking layer 18 is disposed on a first surface 16a of the quantum dot layer 16.

In some embodiments, the light-emitting unit 12 includes a micro light-emitting diode (ILED), but the present disclosure is not limited thereto. In some embodiments, the light-emitting unit 12 emits ultraviolet light or blue light, but the present disclosure is not limited thereto. The light-emitting unit 12 also emits light of other wavelengths, such as red light or green light.

In some embodiments, the light-conversion structure 14 includes cadmium sulfide (CdS), cadmium selenide (CdSe), cadmium telluride (CdTe), or other suitable semiconductor particles or crystal which is capable of wavelength conversion, but the present disclosure is not limited thereto.

In some embodiments, the etching blocking layer 18 may be used as a patterned mask, wherein the material of the etching blocking layer 18 includes an inorganic transparent insulating material, such as silicon oxide, silicon nitride, or other suitable inorganic transparent dielectric materials, but the present disclosure is not limited thereto. In some embodiments, the silicon oxide material which is selected for the etching blocking layer 18 includes silicon dioxide (SiO₂) In some embodiments, the silicon nitride material which is selected for the etching blocking layer 18 includes silicon nitride (Si₃N₄). In some embodiments, the etching blocking layer 18 may be a transparent insulating layer. In some embodiments, the etching blocking layer 18 may be an organic transparent insulating layer.

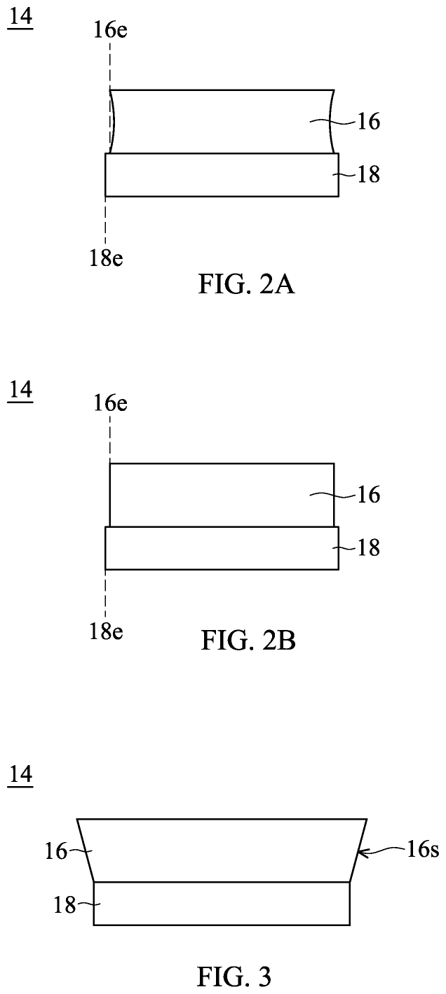

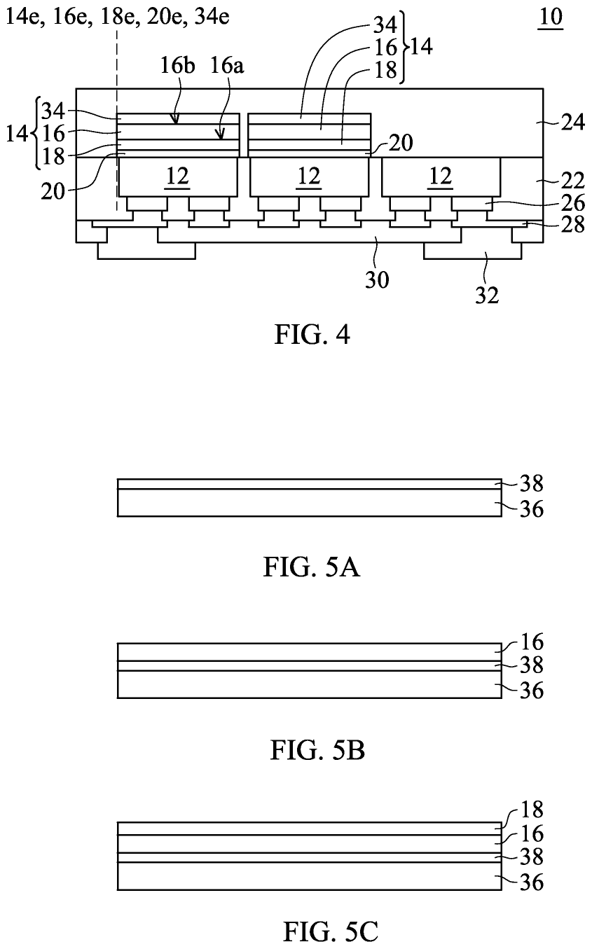

In some embodiments, due to the implementation of the process (e.g. patterning process), a variety of different structures and profiles may be formed between the quantum dot layer 16 and the etching blocking layer 18. For example, referring to FIG. 1, an edge 16e of the quantum dot layer 16 may be aligned with an edge 18e of the etching blocking layer 18, but the present disclosure is not limited thereto. Under the implementation of the process, other structures and profiles formed between the quantum dot layer 16 and the etching blocking layer 18 are also included in the present disclosure. For example, in some embodiments, as shown in FIGS. 2A and 2B, the edge 16e of the quantum dot layer 16 relative to the edge 18e of the etching blocking layer 18 is bent inwardly. For example, in some embodiments, as shown in FIG. 3, a side wall 16s of the quantum dot layer 16 is an inclined plane.

In some embodiments, the light-emitting device 10 further includes an adhesive layer 20, which is disposed between the light-emitting unit 12 and the light-conversion structure 14. In some embodiments, the adhesive layer 20 may include polyimide (PI), epoxy, or silicone, but the present disclosure is not limited thereto. Other suitable polymer materials with adhesion capability may also be suitable for the embodiments in the present disclosure.

In some embodiments, an edge 14e of the light-conversion structure 14 may be aligned with an edge 20e of the adhesive layer 20, but the present disclosure is not limited thereto. Under the implementation of the process, other structures and profiles formed between the light-conversion structure 14 and the adhesive layer 20 are also included in the present disclosure.

In some embodiments, the light-emitting device 10 further includes a covering layer 22 surrounding the light-emitting unit 12. In some embodiments, the covering layer 22 may include polyimide (PI) or epoxy, but the present disclosure is not limited thereto. Other materials with appropriate dielectric constant and step coverage are also applicable. In some embodiments, the thickness of the covering layer 22 may be greater than 10 μm, for example, which may cover the light-emitting unit 12. In some embodiments, the covering layer 22 further includes a black matrix material. In some embodiments, the black matrix material includes suitable shading materials, for example, epoxy or carbon black, but the present disclosure is not limited thereto. In some embodiments, the proportion of the black matrix material in the covering layer 22 is about 10%-95%. In some embodiments, the proportion of the black matrix material in the covering layer 22 is about 100%.

In some embodiments, the light-emitting device 10 further includes an encapsulation material 24, covering the light-emitting unit 12 and the light-conversion structure 14. In some embodiments, the encapsulation material 24 may include suitable molding compound, for example, epoxy molding compound (EMC), liquid molding compound (LMC), or polysiloxane (silicone), but the present disclosure is not limited thereto. In some embodiments, light transmittance of the encapsulation material 24 may be greater than 90%. In some embodiments, the thickness of the encapsulation material 24 may be greater than 50 μm.

As shown in FIG. 1, an electrode 26 of the light-emitting unit 12 is connected to a redistribution layer (RDL) 28. A protective layer 30 may be disposed on the covering layer 22 and expose a portion of the redistribution layer 28. The exposed portion of the redistribution layer 28 may be connected with solder 32. The light-emitting device 10 may be connected to an external circuit (not shown), such as a printed circuit board (PCB), by solder 32.

In some embodiments, the electrode 26 may include suitable metal materials, for example, chromium, aluminum, nickel, gold, platinum, tin, copper, or alloys thereof, but the present disclosure is not limited thereto. In some embodiments, the redistribution layer 28 may include suitable metal materials, for example, chromium, aluminum, nickel, gold, platinum, tin, copper, or alloys thereof, but the present disclosure is not limited thereto. In some embodiments, the protective layer 30 may include suitable organic or inorganic insulating materials, for example, silicon dioxide (SiO₂), epoxy, polyimide (PI), or silicone, but the present disclosure is not limited thereto. In some embodiments, solder 32 may include solder material, such as silver solder, copper solder, or cadmium solder, but the present disclosure is not limited thereto. In some embodiments, solder 32 may include solder material, such as Sn—Pb alloy solder, antimony added solder, but the present disclosure is not limited thereto. In some embodiments, solder 32 may include suitable soft solder, but the present disclosure is not limited thereto. In some embodiments, solder 32 may include suitable hard solder, but the present disclosure is not limited thereto.

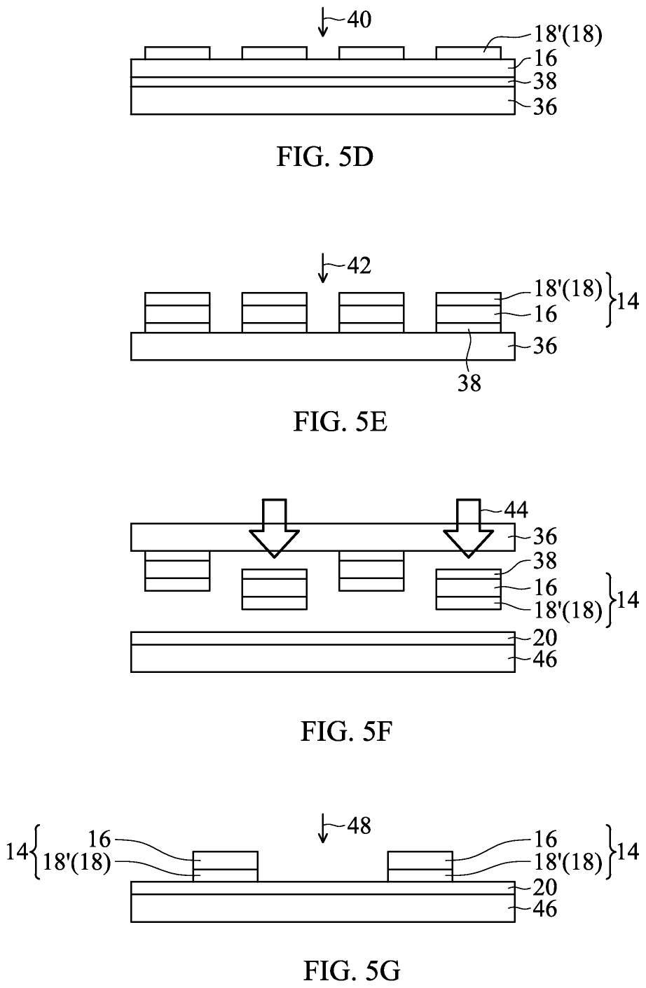

Referring to FIG. 4, a light-emitting device 10 in accordance with another embodiment of the present disclosure is provided. FIG. 4 shows a schematic sectional view of the light-emitting device 10.

As shown in FIG. 4, the parts similar to those disclosed in FIG. 1 will not be repeated here. As shown in FIG. 4, the main difference from FIG. 1 is that the light-emitting device 10 further includes a transparent protective layer 34 disposed on the other surface of the quantum dot layer 16. In detail, as shown in FIG. 4, the light-conversion structure 14 of the light-emitting device 10 includes the quantum dot layer 16, the etching blocking layer 18, and the transparent protective layer 34. The etching blocking layer 18 may be disposed on the first surface 16a of the quantum dot layer 16, and the transparent protective layer 34 may be disposed on a second surface 16b of the quantum dot layer 16.

In some embodiments, the transparent protective layer 34 may include an inorganic transparent insulating material, such as silicon oxide material or silicon nitride material, but the present disclosure is not limited thereto. Other suitable inorganic transparent dielectric materials may also be suitable for the embodiments. In some embodiments, the silicon oxide material selected for the transparent protective layer 34 may include silicon dioxide. Other suitable silicon oxide materials may also be suitable for the embodiments in the present disclosure. In some embodiments, the silicon nitride material selected for the transparent protective layer 34 may include silicon nitride (Si₃N₄), but the present disclosure is not limited thereto. Other suitable silicon nitride materials may also be suitable for the embodiments. In some embodiments, the transparent protective layer 34 may be a transparent insulating layer.

In some embodiments, due to the implementation of the process (e.g. patterning process), a variety of different structures and profiles may be formed between the quantum dot layer 16 and the transparent protective layer 34. For example, referring to FIG. 4, the edge 16e of the quantum dot layer 16 may be aligned with an edge 34e of the transparent protective layer 34, but the present disclosure is not limited thereto. Under the implementation of the process, other structures and profiles formed between the quantum dot layer 16 and the transparent protective layer 34 are also included in the present disclosure. For example, in some embodiments, the edge 16e of the quantum dot layer 16 relative to the edge 34e of the transparent protective layer 34 is bent inwardly (not shown). For example, in some embodiments, the side wall of the quantum dot layer 16 and a side wall of the transparent protective layer 34 are an inclined plane (not shown).

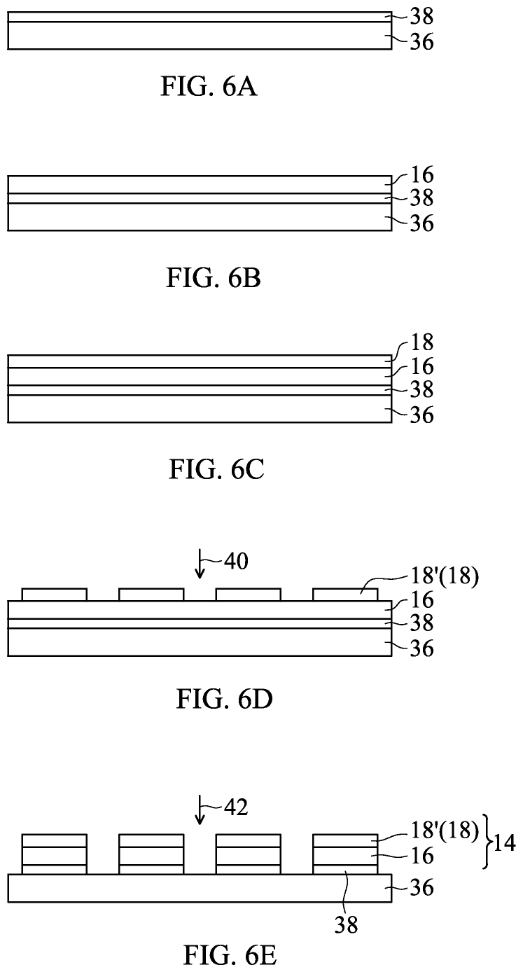

Referring to FIGS. 5A-5G, a method for producing a light-emitting device in accordance with an embodiment of the present disclosure is provided. FIGS. 5A-5G show schematic sectional views of the method for producing the light-emitting device.

As shown in FIG. 5A, a substrate 36 is provided. Next, an adhesive layer 38 is formed on the substrate 36. In some embodiments, the method of forming the adhesive layer 38 may include taping or coating, but the present disclosure is not limited thereto. Other suitable forming method are also suitable for the embodiments. In some embodiments, the substrate 36 may include glass or quartz, but the present disclosure is not limited thereto. In some embodiments, the substrate 36 may include sapphire, but the present disclosure is not limited thereto. In some embodiments, the substrate 36 may include transparent polymer materials, but the present disclosure is not limited thereto. Other suitable transparent substrates may also be suitable for the embodiments. In some embodiments, the adhesive layer 38 may include polyimide (PI), epoxy, or silicone, but the present disclosure is not limited thereto. Other suitable polymer materials having adhesion capability and easily to be dissociated by laser lift-off (LLO) are also included in the present disclosure.

Next, as shown in FIG. 5B, a quantum dot layer 16 is formed on the adhesive layer 38. In some embodiments, the method of forming the quantum dot layer 16 may include taping or coating, but the present disclosure is not limited thereto. Other suitable forming method are also suitable for the embodiments. In some embodiments, the quantum dot layer 16 may include cadmium sulfide (CdS), cadmium selenide (CdSe), or cadmium telluride (CdTe), other suitable semiconductor particles or crystal which is capable of wavelength conversion, but the present disclosure is not limited thereto.

Next, as shown in FIG. 5C, an etching blocking layer 18 is formed on the quantum dot layer 16. In some embodiments, the method of forming the etching blocking layer 18 may include sputtering, spin-coating, low-pressure chemical vapor deposition (LPCVD), low-temperature chemical vapor deposition (LTCVD), rapid thermal chemical vapor deposition (RTCVD), plasma enhanced chemical vapor deposition (PECVD), atomic layer deposition (ALD), physical vapor deposition (PVD), molecular beam deposition, or a combination thereof, but the present disclosure is not limited thereto. Other suitable forming method are also suitable for the embodiments. In some embodiments, the etching blocking layer 18 may be used as a patterned mask, wherein the material of the etching blocking layer 18 includes an inorganic transparent insulating material, such as silicon oxide or silicon nitride, but the present disclosure is not limited thereto. Other suitable inorganic transparent dielectric materials may also be suitable for the embodiments. In some embodiments, the silicon oxide material which is selected for the etching blocking layer 18 includes silicon dioxide (SiO₂), but the present disclosure is not limited thereto. In some embodiments, the silicon nitride material which is selected for the etching blocking layer 18 includes silicon nitride (Si₃N₄), but the present disclosure is not limited thereto. In some embodiments, the etching blocking layer 18 may be a transparent insulating layer.

As shown in FIG. 5C, the etching blocking layer 18 is formed on one of the surfaces of the quantum dot layer 16. In some embodiments, before forming the quantum dot layer 16, a transparent protective layer (not shown) may be formed on the adhesive layer 38 first, so that an upper surface and a lower surface of the quantum dot layer 16 may be respectively formed with the etching blocking layer 18 and the above transparent protective layer.

In some embodiments, the above transparent protective layer includes an inorganic transparent insulating material, such as silicon oxide or silicon nitride, but the present disclosure is not limited thereto. Other suitable inorganic transparent dielectric materials may also be suitable for the embodiments. In some embodiments, the silicon oxide material which is selected for the above transparent protective layer includes silicon dioxide (SiO₂), but the present disclosure is not limited thereto. In some embodiments, the silicon nitride material which is selected for the above transparent protective layer includes silicon nitride (Si₃N₄), but the present disclosure is not limited thereto. In some embodiments, the above transparent protective layer may be a transparent insulating layer.

As shown in FIG. 5D, a patterning process 40 is performed to form a patterned etching blocking layer 18′. In some embodiments, using a patterned photoresist layer (not shown) as an etching mask, and by etching process, such as reactive ion etch (RIE), neutral beam etch (NBE), inductively coupled plasma etch (ICP), or other suitable method, or a combination thereof, perform the patterning process of etching blocking layer 18, so that the etching blocking layer 18′ is formed. Then, the patterned photoresist layer is removed by etching process or other suitable methods.

Next, as shown in FIG. 5E, using the patterned etching blocking layer 18′ as a mask, a patterning process 42 is performed to form a light-conversion structure 14. In some embodiments, using the patterned etching blocking layer 18′ as an etching mask, and by etching process, such as reactive ion etch (RIE), neutral beam etch (NBE), or other suitable method, or a combination thereof, the patterning process is performed on the quantum dot layer 16 and the adhesive layer 38 so that the light-conversion structure 14 is formed.

In some embodiments, due to the implementation of the patterning process, a variety of different structures and profiles may be formed between the quantum dot layer 16 and the etching blocking layer 18 of the light-conversion structure 14. For example, referring to FIG. 1, the edge 16e of the quantum dot layer 16 may be aligned with the edge 18e of the etching blocking layer 18, but the present disclosure is not limited thereto. Under the implementation of the process, other structures and profiles formed between the quantum dot layer 16 and the etching blocking layer 18 are also included in the present disclosure. For example, in some embodiments, as shown in FIGS. 2A and 2B, the edge 16e of the quantum dot layer 16 relative to the edge 18e of the etching blocking layer 18 is bent inwardly. For example, in some embodiments, as shown in FIG. 3, the side wall 16s of the quantum dot layer 16 is an inclined plane.

Next, referring to FIG. 5F, a mass transfer process 44 is performed to transfer the light-conversion structure 14 onto a target structure 46 which is covered with the adhesive layer 20, as shown in FIG. 5G. In some embodiments, the mass transfer process 44 may include a laser transfer process, a stamp transfer process, or other suitable methods, but the present disclosure is not limited thereto. For example, as shown in FIG. 5F, by the laser transfer process, the adhesive layer 38 is thermally decomposed under laser, so that the light-conversion structure 14 is peeled off from the substrate 36 and transferred to the target structure 46. In some embodiments, the energy of the laser light in the laser transfer process may be greater than 0.5 millijoule per millimeter squared. When the energy of the laser light is too high, it may damage the light-conversion structure 14, or after the excessive energy is absorbed by the adhesive layer 38, an excessively high impact energy is generated, which may damage that the light-conversion structure 14 when the light-conversion structure 14 hits the adhesive layer 20. When the energy of the laser light is too low, it may not effectively transfer the light-conversion structure 14, or the impact energy is not enough, the light-conversion structure 14 may not effectively stand on the adhesive layer 20. In some embodiments, the adhesive layer 20 may include polyimide (PI), epoxy, or silicone, but the present disclosure is not limited thereto. Other suitable polymer materials having adhesion capability and easily to be dissociated by laser lift-off (LLO) are also included in the present disclosure.

Next, as shown in FIG. 5G, a cleaning process 48 is performed to remove the adhesive layer 38 remaining on the light-conversion structure 14. In some embodiments, the cleaning process 48 may include a plasma process, but the present disclosure is not limited thereto. Thus, manufacture of the light-emitting device in the embodiment is completed, wherein the target structure 46 may include a partial structure as shown in FIG. 1. For example, the structure arranged under the adhesive layer 20 may include the light-emitting unit 12 and the covering layer 22.

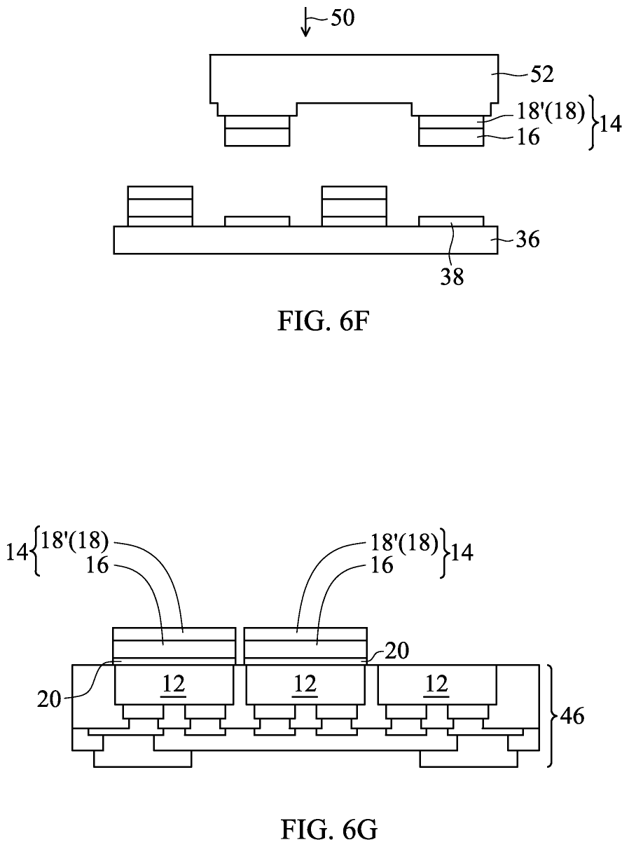

Referring to FIGS. 6A-6G, a method for producing a light-emitting device in accordance with another embodiment of the present disclosure is disclosed. FIGS. 6A-6G show schematic sectional views of the method for producing the light-emitting device.

In another embodiment shown in FIGS. 6A-6G, the process steps shown in FIGS. 6A-6E are similar to the process steps shown in FIGS. 5A-5E, and will not be repeated here. The main difference between the two embodiments is that the stamp transfer process 50 in FIG. 6F replaces the laser transfer process in FIG. 5F. As shown in FIG. 6G, it is noted that after the stamp transfer process 50, the etching blocking layer 18 may be formed on the quantum dot layer 16 in the light-conversion structure 14. However, after the laser transfer process, the quantum dot layer 16 may be formed on the etching blocking layer 18 in the light-conversion structure 14. In addition, during the stamp transfer process 50, by the stamp head 52 having a higher surface adhesion force than that of the adhesive layer 38 on the substrate 36, some of the light-conversion structures 14 are selected and picked up by the stamp head 52. Because the surface adhesion force of the adhesive layer 20 on the light-emitting unit 12 is higher than that of the stamp head 52, the selected light-conversion structure 14 are disposed onto the light-emitting unit 12, as shown in FIG. 6G.

The present disclosure transfers the quantum dot layer (such as red quantum dot layer or green quantum dot layer) onto the light-emitting unit (such as an ultraviolet LED or blue LED) by the mass transfer process (such as laser transfer process or stamp transfer process), in which the etching blocking layer (e.g. silicon dioxide) is disposed on one of the surfaces of the quantum dot layer. The quantum dot layer converts the wavelength of received light into the desired wavelength, and then configures a LED package including red, green, and blue three colors.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments can be combined or substituted under proper condition and are not limited to specific embodiments described above. A connection relationship between a specific component and another component specifically described in an embodiment can also be applied in another embodiment and is within the scope as claimed in the present disclosure.

What is claimed is:

1. A light-emitting device, comprising:
a light-emitting unit; and
a light-conversion structure disposed on the light-emitting unit;
wherein the light-conversion structure comprising:
a quantum dot layer, wherein the quantum dot layer has surfaces; and
an etching blocking layer disposed on one of the surfaces of the quantum dot layer.

2. The light-emitting device of claim 1, wherein the etching blocking layer includes an inorganic transparent insulating material.

3. The light-emitting device of claim 2, wherein the etching blocking layer includes silicon dioxide.

4. The light-emitting device of claim 1, wherein the etching blocking layer includes a transparent insulating layer.

5. The light-emitting device of claim 1, wherein an edge of the quantum dot layer is aligned with an edge of the etching blocking layer.

6. The light-emitting device of claim 1, further comprising a transparent protective layer disposed on the other surface of the quantum dot layer.

7. The light-emitting device of claim 1, further comprising an adhesive layer disposed between the light-emitting unit and the light-conversion structure.

8. The light-emitting device of claim 7, wherein an edge of the light-conversion structure is aligned with an edge of the adhesive layer.

9. The light-emitting device of claim 1, further comprising a covering layer surrounding the light-emitting unit.

10. The light-emitting device of claim 9, wherein the covering layer further includes a black matrix material.

11. The light-emitting device of claim 1, wherein a side wall of the quantum dot layer comprises an inclined plane.

12. The light-emitting device of claim 1, wherein the light-emitting unit includes a micro light-emitting diode (μLED).

13. The light-emitting device of claim 1, wherein the light-emitting unit emits ultraviolet light or blue light.

14. The light-emitting device of claim 7, the adhesive layer includes polyimide (PI), epoxy, or silicone.

15. A method of forming light-emitting device, comprising:
providing a substrate;
forming an adhesive layer on the substrate;
forming a quantum dot layer on the adhesive layer having a plurality of surfaces;
forming an etching blocking layer disposed on one of the surfaces of the quantum dot layer;
using the etching blocking layer as a patterned mask;
performing a patterning process to form a light-conversion structure;
providing a light-emitting unit; and
transferring the light-conversion structure onto the light-emitting unit.

16. The method of claim 15, wherein form the etching blocking layer on the quantum dot layer by a low-temperature deposition process.

17. The method of claim 15, wherein transferring the light-conversion structure onto the light-emitting unit includes a laser transfer process or a stamp transfer process.

18. The method of claim 15, further comprising:
forming a transparent protective layer disposed on the other surface of the quantum dot layer.

19. The method of claim 15, wherein the etching blocking layer includes a transparent insulating layer.

20. The method of claim 17, wherein the energy of the laser light in the laser transfer process is greater than 0.5 millijoule per millimeter squared.
